(19) United States
(12) Patent Application Publication
(10) Pub. No.: US 2011/0248277 A1
(43) Pub. Date: Oct. 13, 2011

(54) METHOD OF CRYSTALIZING AMORPHOUS SILICON LAYER, METHOD OF MANUFACTURING THIN FILM TRANSISTOR USING THE SAME, AND THIN FILM TRANSISTOR USING THE MANUFACTURING METHOD

(75) Inventors: Dong-Hyun LEE, Yongin-City (KR); Ki-Yong LEE, Yongin-City (KR); Jin-Wook Seo, Yongin-City (KR); Min-Jae Jeong, Yongin-City (KR); Yong-Duck Son, Yongin-City (KR); Byung-Soo So, Yongin-City (KR); Seung-Kyu Park, Yongin-City (KR); Kil-Won Lee, Yongin-City (KR); Yun-Mo Chung, Yongin-City (KR); Byoung-Keon Park, Yongin-City (KR); Jong-Ryuk Park, Yongin-City (KR); Tak-Young Lee, Yongin-City (KR); Jae-Wan Jung, Yongin-City (KR)

(73) Assignee: Samsung Mobile Display Co., Ltd., Yongin-City (KR)

(21) Appl. No.: 12/975,809

(22) Filed: Dec. 22, 2010

(30) Foreign Application Priority Data
Apr. 8, 2010 (KR) 10-2010-0032337

(51) Int. Cl. H01L 27/12; H01L 21/20; H01L 21/84

(52) U.S. Cl. 257/66; 438/166; 438/486; 257/E27.112; 257/E21.703; 257/E21.09

(57) ABSTRACT

A method of crystallizing an amorphous silicon layer, a method of manufacturing a thin film transistor using the same, and a thin film transistor using the manufacturing method, the crystallizing method including: forming an amorphous silicon layer; positioning crystallization catalyst particles on the amorphous silicon layer to be separated from each other; selectively removing the crystallization catalyst particles from a portion of the amorphous silicon layer; and crystallizing the amorphous silicon layer by a heat treatment.

### CROSS-REFERENCE TO RELATED APPLICATIONS

This application claims priority to and the benefit of Korean Patent Application No. 10-2010-0032337 filed in the Korean Intellectual Property Office on Apr. 8, 2010, the entire contents of which are incorporated herein by reference.

### BACKGROUND

1. Field

The described technology relates generally to a method of crystallizing an amorphous silicon layer, a method of manufacturing a thin film transistor using the same, and a thin film transistor using the manufacturing method.

2. Description of the Related Art

A display, such as an active-matrix-type liquid crystal display or an organic light emitting diode display, includes thin film transistors. A polysilicon layer, being superior in electric field effect mobility and stability against temperature and light, is generally used as a semiconductor layer for the thin film transistors.

The polysilicon layer is formed by crystallizing an amorphous silicon layer, and a laser process or the like is widely used as a crystallizing method. Examples of the laser process include an excimer laser annealing (ELA) method, which momentarily irradiates a high-power excimer laser pulse, an sequential lateral solidification (SLS) method, which induces lateral growth of silicon crystals, an metal induced crystallization (MIC) method, using spreading of a metal catalyst, a metal induced crystallization (MILC) method of inducing growth of silicon crystals by using spread of a crystallization catalyst, or other similar methods.

Among them, the MIC method or the MILC method is effective in that fine polysilicon crystals can be obtained. However, if an amount of residual crystallization catalyst used in crystallization is large in a semiconductor layer, it may cause current leakage, resulting in a degradation in properties of the thin film transistors.

The above information disclosed in this Background section is only for enhancement of understanding of the background of the described technology and therefore it may contain information that does not form the prior art that is already known in this country to a person of ordinary skill in the art.

### SUMMARY

Aspects of the present invention provide a method of crystallizing an amorphous silicon layer having advantages of effectively gettering a metal catalyst when a semiconductor layer containing polysilicon is formed by using a spread of the metal catalyst. Thus, an amount of residual metal catalyst in a semiconductor layer is reduced. Moreover, aspects of the present invention have been made to provide a method of manufacturing a thin film transistor using the method of crystallizing an amorphous silicon layer, and a thin film transistor manufactured thereby.

Aspects of the present invention provide a crystallizing method including: forming an amorphous silicon layer; positioning crystallization catalyst particles on the amorphous silicon layer to be separated from each other; selectively removing the crystallization catalyst particles from a portion of the amorphous silicon layer; and crystallizing the amorphous silicon layer by a heat treatment.

According to an aspect of the present invention, a crystallization region crystallized in the crystallizing of the amorphous silicon layer may include a first region positioned below the crystallization catalyst particles and crystallized by super grain silicon (SGS) or metal induced crystallization (MIC), and second regions positioned on both sides of the first region and crystallized by metal induced lateral crystallization (MILC).

According to an aspect of the present invention, the crystallizing method may further include removing an uncrystallized region after the crystallizing of the amorphous silicon layer.

According to an aspect of the present invention, the selectively removing of the crystallization catalyst particles may include forming an insulating layer to cover the crystallization catalyst particles, and patterning the insulating layer.

According to an aspect of the present invention, the crystallizing method may further include forming an auxiliary insulating layer on the amorphous silicon layer between the forming of the amorphous silicon layer and the positioning of the crystallization catalyst particles.

According to an aspect of the present invention, in the patterning of the insulating layer, the auxiliary insulating layer may be patterned together with the insulating layer in a same pattern as the insulating layer. The crystallizing method may further include patterning the auxiliary insulating layer in the same pattern as the insulating layer after the crystallizing of the amorphous silicon layer.

According to an aspect of the present invention, the crystallization catalyst particles may include nickel (Ni), and the crystallization catalyst particles may be deposited at a density of 10¹¹ to 10¹⁵ particles/cm² in the positioning of the crystallization catalyst particles.

According to an aspect of the present invention, the heat treatment of the crystallizing of the amorphous silicon layer may be performed at a temperature 200° C. to 900° C.

Aspects of the present invention provide a method of manufacturing a thin film transistor including a semiconductor layer having a channel region, a source region and drain region defined, a gate electrode formed corresponding to the channel region with a gate insulating layer interposed therebetween, and a source electrode and a drain electrode respectively electrically connected to the source region and the drain region. In this manufacturing method, forming the semiconductor layer includes: forming an amorphous silicon layer, positioning crystallization catalyst particles to be separated from each other, selectively removing the crystallization catalyst particles from a portion of the amorphous silicon layer; and crystallizing the amorphous silicon layer by a heat treatment.

According to an aspect of the present invention, a crystallization region crystallized in the crystallizing may include a first region positioned below the crystallization catalyst particles and crystallized by super grain silicon (SGS) or metal induced crystallization (MIC), and second regions positioned on both sides of the first region and crystallized by metal induced lateral crystallization (MILC).

According to an aspect of the present invention, the manufacturing method may further include removing an uncrystallized region after the crystallizing of the amorphous silicon layer.

According to an aspect of the present invention, the selectively removing of the crystallization catalyst particles may include forming an insulating layer to cover the crystallization catalyst particles, and patterning the insulating layer.

According to an aspect of the present invention, the manufacturing method may further include forming an auxiliary insulating layer on the amorphous silicon layer between the forming of the amorphous silicon layer and the positioning of the crystallization catalyst particles.

According to an aspect of the present invention, in the patterning of the insulating layer, the auxiliary insulating layer may be patterned together with the insulating layer in a same pattern as the insulating layer. The manufacturing method may further include patterning the auxiliary insulating layer in the same pattern as the insulating layer after the crystallizing of the amorphous silicon layer. The insulating layer and the auxiliary insulating layer may have different etch selection values.

According to an aspect of the present invention, either the insulating layer, or the insulating layer and the auxiliary insulating layer may be removed after the crystallizing of the amorphous silicon layer.

According to an aspect of the present invention, in the selectively positioning of the crystallization catalyst particles, the crystallization catalyst particles may be positioned corresponding to the channel region. Also, the channel region may include the first region and both the source region and the drain region include the second regions.

According to an aspect of the present invention, in this case, the manufacturing method may further include removing an uncrystallized region after the crystallizing of the amorphous silicon layer. Here, in the removing of the uncrystallized region, the whole uncrystallized region may be removed such that both the source region and the drain region include only the second regions. Alternatively, in the removing of the uncrystallized region, only a portion of the uncrystallized region may be removed such that both the source region and the drain region include portions of the uncrystallized region together with the second regions.

According to an aspect of the present invention, in the selectively positioning of the crystallization catalyst particles, the crystallization catalyst particles may be positioned corresponding to a portion of, or the whole of, the source region and the drain region. Also, the channel region may include the second regions and both the source region and the drain region may include the first region.

According to an aspect of the present invention, in this case, the manufacturing method may further include removing an uncrystallized region after the crystallizing of the amorphous silicon layer. Here, in the removing of the uncrystallized region, the second regions on the outer side of the first region may be removed together with the uncrystallized region such that both the source region and the drain region include only the first region. Alternatively, in the removing of the uncrystallized region, the uncrystallized region may be removed such that both the source region and the drain region include the second regions together with the first region.

According to an aspect of the present invention, the manufacturing method may further include forming the gate electrode and forming the gate insulating layer on the gate electrode before the forming of the semiconductor layer, and forming the source and drain electrodes after the forming of the semiconductor layer. Therefore, it is possible to manufacture a thin film transistor having a bottom gate structure.

According to an aspect of the present invention, the manufacturing method, after the forming of the semiconductor layer, may further include forming the source electrode and the drain electrode, forming the gate insulating layer on the insulating layer, the source electrode and the drain electrode, and forming the gate electrode on the gate insulating layer. Therefore, it is possible to manufacture a thin film transistor having a top gate structure.

According to an aspect of the present invention, the insulating layer may function as an etch stopper of the source electrode and the drain electrode.

According to an aspect of the present invention, the crystallization catalyst particles may include nickel (Ni), and the crystallization catalyst particles may be deposited at a density of 10¹¹ to 10¹⁵ particles/cm² in the positioning of the crystallization catalyst particles.

According to an aspect of the present invention, the heat treatment of the crystallizing of the amorphous silicon layer may be performed at a temperature 200° C. to 900° C.

Aspects of the present invention provide a thin film transistor including: a semiconductor layer having a channel region, a source region and a drain region defined; a gate electrode formed corresponding to the channel region with a gate insulating layer interposed therebetween; a source electrode electrically connected to the source region; and a drain electrode electrically connected to the drain region. The channel region may include a first region crystallized by super grain silicon (SGS) or metal induced crystallization (MIC), and both the source region and the drain region may include second regions crystallized by metal induced lateral crystallization (MILC).

According to an aspect of the present invention, both the source region and the drain regions may include only the second regions. Alternatively, both the source region and the drain region may include an uncrystallized region formed of amorphous silicon together with the second regions.

According to an aspect of the present invention, the thin film transistor may further include an insulating layer formed corresponding to the channel region. The thin film transistor may further include an auxiliary insulating layer disposed between the insulating layer and the semiconductor layer.

According to an aspect of the present invention, the thin film transistor according to the present embodiment may have a bottom gate structure, in which the gate insulating layer is positioned on the gate electrode, the semiconductor layer is positioned on the gate insulating layer, the insulating layer is positioned on the semiconductor layer, and the source electrode and the drain electrode are positioned on the semiconductor layer.

According to an aspect of the present invention, the thin film transistor according to the present embodiment may have a top gate structure, in which the insulating layer is positioned on the semiconductor layer, the source electrode and the drain electrode are positioned on the semiconductor layer, the gate insulating layer is positioned on the source electrode and the drain electrode, and the gate electrode is positioned on the gate insulating layer.

According to an aspect of the present invention, the insulating layer may function as an etch stopper of the source electrode and the drain electrode.

In the thin film transistor according to aspects of the present invention, an amount of crystallization catalyst particles contained in an interface between the insulating layer and the semiconductor layer may be larger than an amount of crystallization catalyst particles in the insulating layer or the semiconductor layer.

In the thin film transistor according to aspects of the present invention, an amount of crystallization catalyst particles contained in an interface between the insulating layer and the auxiliary insulating layer may be larger than an amount of crystallization catalyst particles in the insulating layer or the auxiliary insulating layer.

According to aspects of the present invention, the method of crystallizing an amorphous silicon layer can spread crystallization catalyst particles into a selected region of an amorphous silicon layer containing no crystallization catalyst particles by performing a heat treatment in a state in which the crystallization catalyst particles are positioned on only the selected region of the amorphous silicon layer. That is, an amorphous silicon layer containing no crystallization catalyst particles can be used for gettering crystallization catalyst particles, which makes it possible to effectively reduce an amount of residual crystallization catalyst particles in a semiconductor layer.

According to aspects of the present invention provide a method of manufacturing a thin film transistor that can reduce an amount of residual crystallization catalyst particles in a semiconductor layer by adapting the method of crystallizing an amorphous silicon layer according to the embodiment described above. Leakage current can be minimized in a thin film transistor manufactured by the method of manufacturing a thin film transistor, resulting in an improvement in the properties of the thin film transistor.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a flowchart illustrating a method of crystallizing an amorphous silicon layer according to an embodiment;

FIGS. 2A to 2F are cross-sectional views sequentially illustrating processes according to the crystallizing method of FIG. 1;

FIGS. 3A to 3H are cross-sectional views sequentially illustrating processes of a method of crystallizing an amorphous silicon layer according to another modified embodiment;

FIGS. 4A to 4G are cross-sectional views sequentially illustrating processes of a method of crystallizing an amorphous silicon layer according to another embodiment;

FIG. 5 is a flowchart illustrating a method of manufacturing a thin film transistor according to another embodiment;

FIGS. 6A to 6D are cross-sectional views sequentially illustrating processes of the method of manufacturing a thin film transistor according to the embodiment of FIG. 5;

FIG. 7 is a cross-sectional view illustrating a thin film transistor manufactured by a method of manufacturing a thin film transistor according to another embodiment;

FIG. 8 is a cross-sectional view illustrating operation of removing an uncrystallized region in a method of manufacturing a thin film transistor according to another embodiment;

FIG. 9 is a cross-sectional view illustrating manufactured by the method of manufacturing a thin film transistor according to the embodiment of FIG. 8;

FIGS. 10A to 10C are cross-sectional views illustrating some of processes of a method of manufacturing a thin film transistor according to another embodiment;

FIG. 11 is a cross-sectional view illustrating a thin film transistor manufactured by the method of manufacturing a thin film transistor according the embodiment of FIGS. 10A to 10C;

FIGS. 12A to 12C are cross-sectional views illustrating some of processes in operation of forming a semiconductor layer of a method of manufacturing a thin film transistor according to another embodiment;

FIG. 13 is a cross-sectional view illustrating a thin film transistor manufactured by the method of manufacturing a thin film transistor according to the embodiment of FIGS. 12A to 12C;

FIG. 14 is a cross-sectional view illustrating operation of selectively removing crystallization catalyst particles of operation of forming a semiconductor layer of a method of manufacturing a thin film transistor according to another embodiment;

FIG. 15 is a cross-sectional view illustrating a thin film transistor manufactured by a method of manufacturing a thin film transistor according to another embodiment;

FIG. 16 is a flowchart illustrating a method of manufacturing a thin film transistor according to another embodiment;

FIG. 17 is a cross-sectional view illustrating a thin film transistor manufactured according to the embodiment of FIG. 16;

FIG. 18 is a cross-sectional view illustrating a thin film transistor according to another embodiment; and

FIG. 19 is a graph illustrating profiles of SIMS (secondary ion mass spectrometry) in the semiconductor layers and the insulating layers in the experimental example and the comparative example, according to aspects of the present invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

It is to be understood that where is stated herein that one element, film or layer is “formed on” or “disposed on” a second element, layer or film, the first element, layer or film may be formed or disposed directly on the second element, layer or film or there may be intervening element, layers or films between the first element, layer or film and the second element, layer or film. Further, as used herein, the term “formed on” is used with the same meaning as “located on” or “disposed on” and is not meant to be limiting regarding any particular fabrication process.

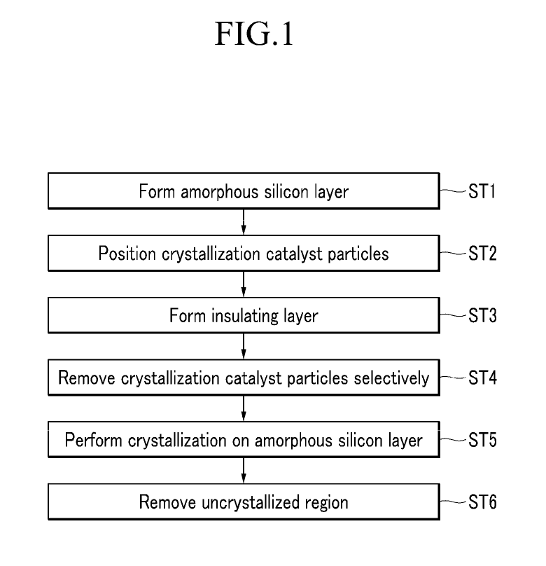

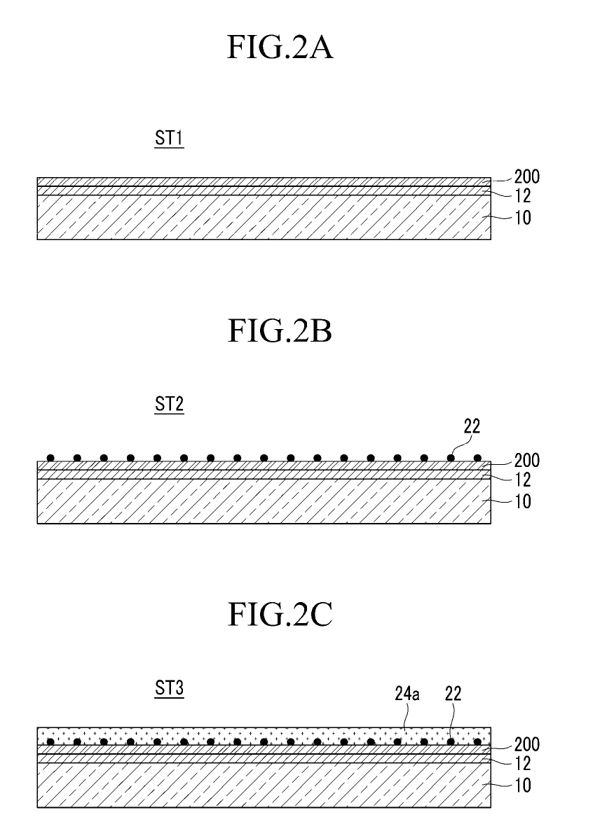

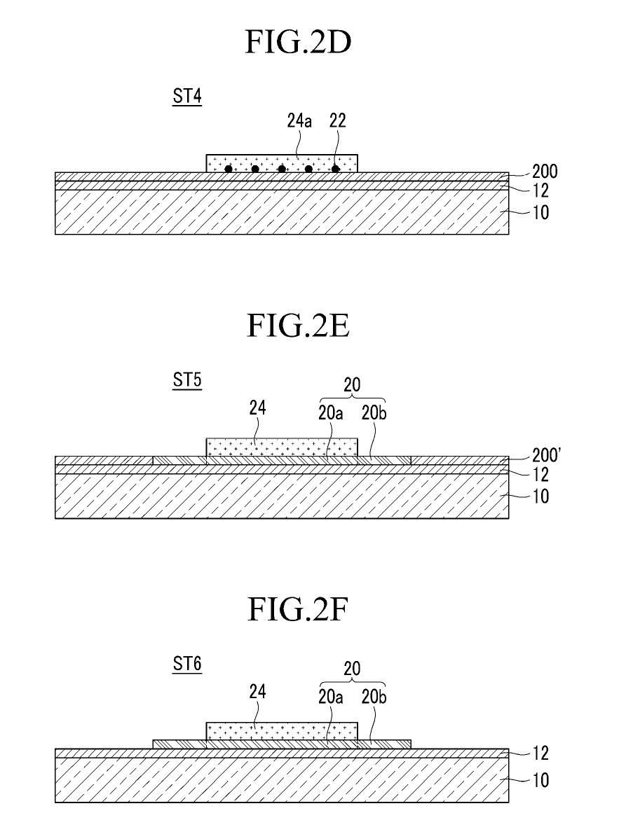

Hereinafter, a method of crystallizing a silicon layer according to an embodiment will be described with reference to FIG. 1 and FIGS. 2A to 2F. FIG. 1 is a flowchart illustrating a method of crystallizing an amorphous silicon layer according to an embodiment. FIGS. 2A to 2F are cross-sectional views sequentially illustrating processes according to the crystallizing method of FIG. 1.

Referring to FIG. 1, the method of crystallizing an amorphous silicon layer includes operation ST1 to form an amorphous silicon layer, operation ST2 to position crystallization catalyst particles, operation ST3 to form an insulating layer, operation ST4 to selectively remove the crystallization catalyst particles, operation ST 5 to perform crystallization on the amorphous silicon layer (ST5), and operation ST6 to remove an uncrystallized region.

As shown in FIG. 2A, in operation ST1 to form an amorphous silicon layer, an amorphous silicon layer 200 is formed on a buffer layer 12 of a substrate 10.

The buffer layer 12 is formed of various materials capable of preventing impure elements from permeating and providing a flattened a surface. For example, the buffer layer 12 is composed of a silicon nitride (SiNx) layer, a silicon oxide (SiO₂) layer, a silicon oxynitride (SiOₓN_{y}) layer, or other similar materials. However, aspects of the present invention are not limited thereto and the buffer layer 12 is not necessarily needed. Thus, the buffer layer 12 may not be formed considering the kind of the substrate 10, process conditions, and other similar conditions.

The amorphous silicon layer 200 is formed by vapor deposition. For example, the amorphous silicon layer 200 is formed by a vapor deposition method such as a PECVD (plasma enhanced chemical vapor deposition) method, an LPCVD (low pressure chemical vapor deposition) method, an HWCVD (hot wire chemical vapor deposition). However, aspects of the present invention are not limited thereto and the amorphous silicon layer 200 can be formed by various methods.

Next, as shown in FIG. 2B, in operation ST2 to position crystallization catalyst particles, crystallization catalyst particles 22 are positioned on the amorphous silicon layer 200 by vapor deposition. In the present embodiment, since only a small amount of crystallization catalyst particles 22 are deposited, the crystallization catalyst particles 22 do not form a film. The crystallization catalyst particles 22 are separated in particle units or in groups. In the FIG. 2B, as an example, there is shown a case in which the crystallization catalyst particles 22 are formed to be separated from each other in particle units.

The crystallization catalyst particles 22 are one or two or more various metallic materials such as nickel (Ni), palladium (Pd), titanium (Ti), silver (Ag), gold (Au), aluminum (Al), tin (Sn), antimony (Sb), copper (Cu), cobalt (Co), chromium (Cr), molybdenum (Mo), terbium (Tb), ruthenium (Ru), cadmium (Cd), platinum (Pd). However, aspects of the present invention are not limited thereto, and other suitable metallic materials may be used.

For example, when nickel (Ni) is used as the crystallization catalyst particles 22, the crystallization catalyst particles 22 may be deposited at a density of 10¹¹ to 10¹⁵ particles/cm². If the crystallization catalyst particles 22 are deposited at a density lower than 10¹¹ particles/cm², there are difficulties in crystallization using a crystallization catalyst because an amount of seeds acting as nuclei of crystallization is small. If the crystallization catalyst particles 22 are deposited at a density exceeding 10¹⁵ particles/cm², an amount of residual crystallization catalyst particles 22 in the amorphous silicon layer 200 increases because an amount of crystallization catalyst particles 22 spread into the amorphous silicon layer 200 increases. The increased residual crystallization catalyst particles 22 degrade properties of a silicon layer after the silicon layer is subjected to crystallization.

Subsequently, as shown in FIGS. 2C and 2D, the crystallization catalyst particles 22 are removed selectively. First, as shown in FIG. 2C, in operation ST3 of forming an insulating layer, an insulating layer 24a is formed to cover the crystallization catalyst particles 22. The insulating layer 24a may be formed of various materials. In the present embodiment, the insulating layer 24a is formed of silicon oxide by vapor deposition.

Next, as shown in FIG. 2D, in operation ST4 of removing the crystallization catalyst particles selectively, patterning is performed on the insulating layer 24a to selectively remove the crystallization catalyst particles 22. That is, if a portion of the insulating layer 24a is removed by patterning, a portion of the crystallization catalyst particles 22 is removed together with the removed portion of the insulating layer 24a. The portion of the insulating layer 24a is removed by etching. However aspects of the present invention are not limited thereto and the portion of the insulating layer 24a can be removed by various methods.

Next, as shown in FIG. 2E, in operation ST5 of performing crystallization on the amorphous silicon layer, a heat treatment is performed to crystallize a portion of the amorphous silicon layer 200 to form a polysilicon region 20.

The heat treatment is performed at a temperature of 200° C. to 900° C., for a duration several seconds to several times the several seconds, to spread the crystallization catalyst particles 22 into the amorphous silicon layer 200. If the heat treatment temperature is lower than 200° C. or the heat treatment time period is too short, the spread of the crystallization catalyst particles 22 may not be smooth. If the heat treatment temperature exceeds 900° C. or the heat treatment time period is too long, the substrate 10 may be distorted. That is, the heat treatment temperature and time period in the present embodiment are determined considering crystallization efficiency, a yield of manufacturing, and a manufacturing cost, and other similar considerations.

In the present embodiment, the heat treatment is performed at a temperature of 400° C. to 750° C. during about 5 minutes to 120 minutes. The heat treatment spreads the crystallization catalyst particles 22 into the insulating layer 24 and into the amorphous silicon layer 200. The crystallization catalyst particles 22 spread into the amorphous silicon layer 200 are combined with silicon (Si) to act as seeds for crystallization amorphous silicon layer 200. Crystals are grown around the seeds in the amorphous silicon layer 200 to form the polysilicon region 20. An uncrystallized region 200′ of the amorphous silicon layer 200 remains at sides of the polysilicon layer 20.

The crystallized polysilicon region 20 includes a first region 20a, which is positioned below the crystallization catalyst particles 22, and also includes second regions 20b which are positioned on two opposite and respective sides of the first region 20a. The first region 20a and the second regions 20b are crystallized by different crystallization mechanisms. The first region 20a, having a relatively large amount of crystallization catalyst particles 22 spread therein, is crystallized by SGS (super grain silicon) or MIC (metal induced crystallization). The second regions 20b, positioned on both sides of the first region 20a, is crystallized by MILC (metal induced lateral crystallization). In the present embodiment, crystallization is performed by SGS, metal induced crystallization or metal induced lateral crystallization. Therefore, the formed polysilicon has fine crystal particles and the manufactured polysilicon region 20 has excellent properties.

In the present embodiment, the crystallization catalyst particles 22 are selectively removed before the heat treatment. Thus, the crystallization catalyst particles 22 are easily spread into a region of the amorphous silicon layer 200 having no crystallization catalyst particles 22 thereon, during the heat treatment process. That is, the region of the amorphous silicon layer 200, having no crystallization catalyst particles 22 thereon, may getter the crystallization catalyst particles. The gettering reduces a concentration of the crystallization catalyst particles 22 in the polysilicon region 20 formed by crystallization.

In a thin film transistor using the polysilicon region 20 as a semiconductor layer, residual crystallization catalyst particles 22 in the polysilicon region 20 may cause leakage current. In the present embodiment, if the polysilicon region 20, having a low concentration of residual crystallization catalyst particles 22, is applied to a thin film transistor, it is possible to minimize leakage current and thus to improve the properties of the thin film transistor.

Subsequently, as shown in FIG. 2F, in operation ST6 of removing an uncrystallized region, the uncrystallized region 200′ (see FIG. 2E) of the amorphous silicon layer 200 is removed by etching. However, aspects of the present invention are not limited thereto, and other suitable methods of removing the uncrystallized region 200′ may be used. In FIG. 2F, there is shown a case in which only the uncrystallized region 200′ has been removed. However, according to a desired shape of a semiconductor layer, the uncrystallized region 200′ may be removed together with a portion of the polysilicon region 20 or a portion of the uncrystallized amorphous region 200′ may remain.

The insulating layer 24 is removed by etching or may remain to be used as an etch stopper or a gate insulation layer in a thin film transistor. A case in which the insulating layer 24 is used as an etch stopper or a gate insulating layer will be described below in more detail in relation to a method of manufacturing a thin film transistor. In the present embodiment, the crystallization catalyst particles 22 are selectively formed, which makes it possible for the portion of the amorphous silicon layer 200, on which there are no the crystallization catalyst particles 22 positioned, to getter the crystallization catalyst particles 22. Therefore, it is possible to reduce the concentration of the crystallization catalyst particles in the polysilicon region 20 and thus to improve the properties of a thin film transistor.

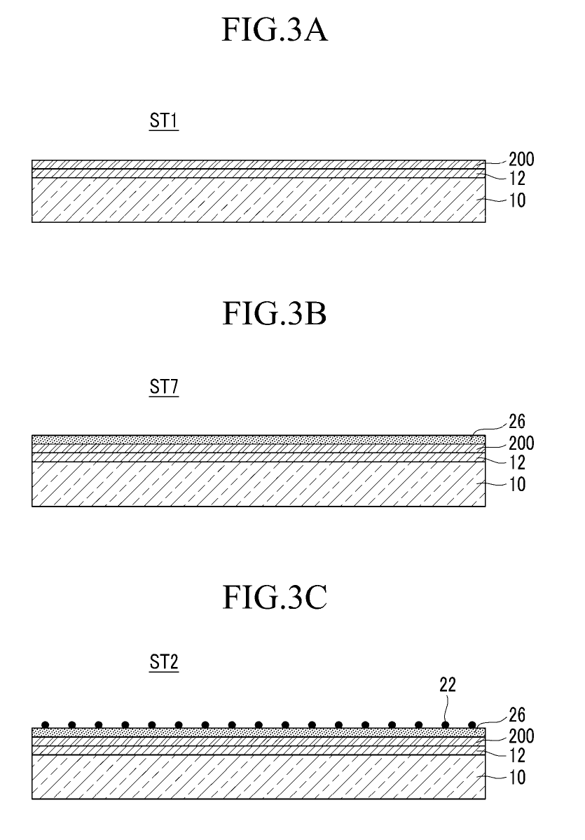

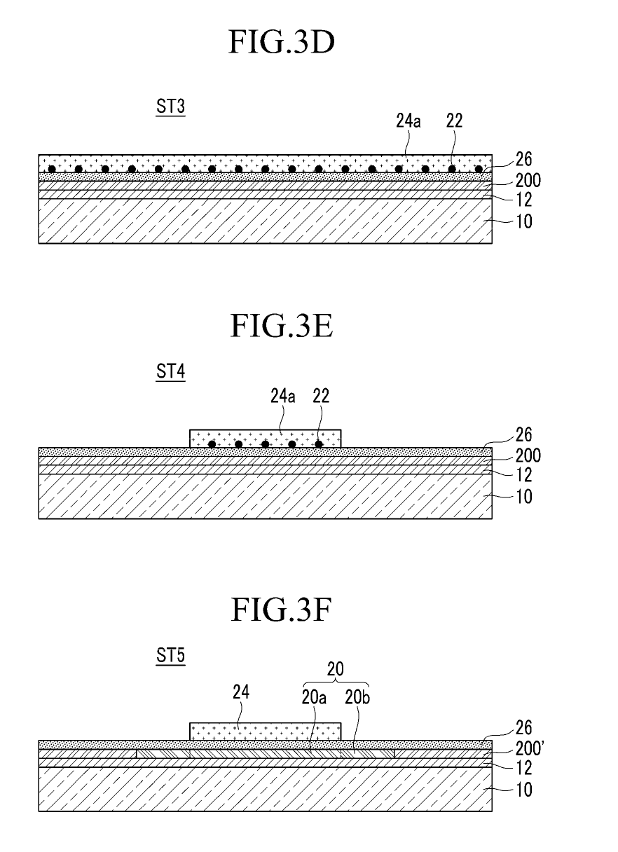

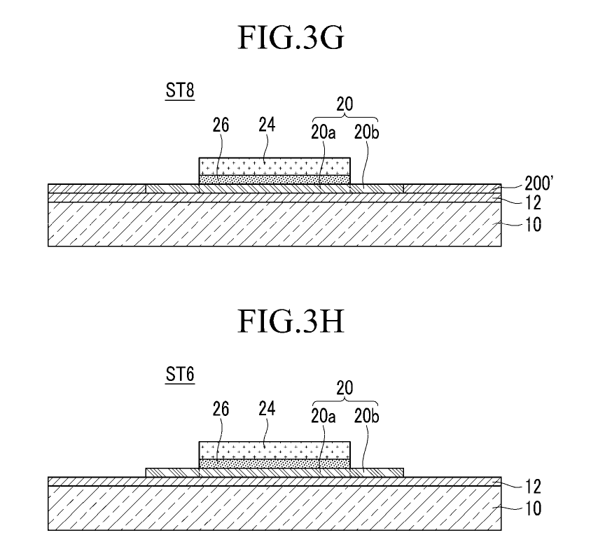

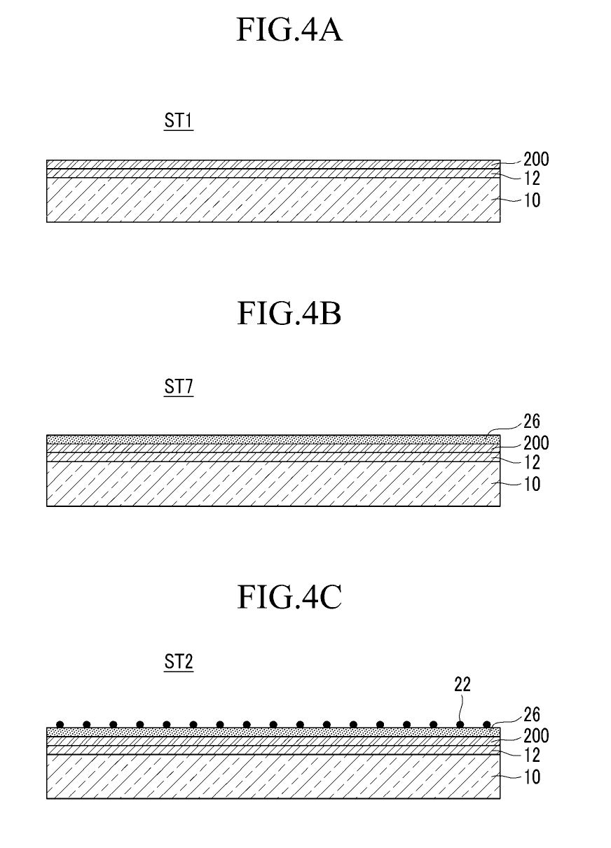

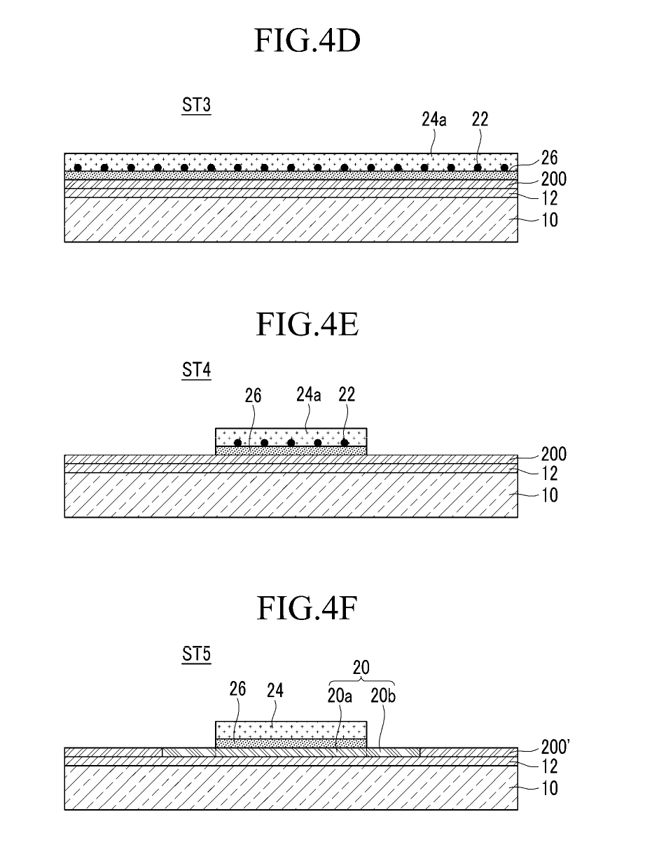

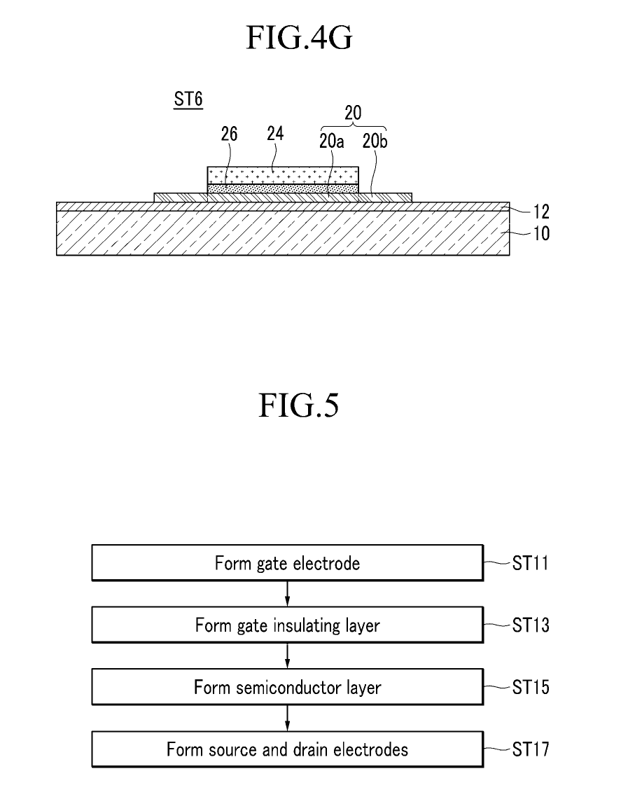

Crystallizing methods according to modified embodiments of the embodiment of FIGS. 2A to 2F will be described below with reference to FIGS. 3A to 3H. and FIGS. 4A to 4G. For the purposes of clear explanation, descriptions of elements or operations similar to the those in the embodiment of FIGS. 2A to 2F will be omitted and only different elements will be described.

FIGS. 3A to 3H are cross-sectional views sequentially illustrating processes of a method of crystallizing an amorphous silicon layer 200 according to another modified embodiment. In the present embodiment, between the operation ST1 to form the amorphous silicon layer 200, as shown in FIG. 3A, and the operation ST2 to position the crystallization catalyst particles 22, as shown in FIG. 3C, an operation ST7 to form an auxiliary insulating layer 26, as shown in FIG. 3B, is further included. Therefore, in the operation ST2 to position the crystallization catalyst particles 22, the crystallization catalyst particles 22 are positioned on the auxiliary insulating layer 26.

Subsequently, operation ST3 to form the insulating layer 24a, as shown in FIG. 3D, operation ST4 to selectively remove the crystallization catalyst particles 22, as shown in FIG. 3E, and operation ST5 to perform crystallization on the amorphous silicon layer, as shown in FIG. 3F, are sequentially performed. Since these operations are the same as those described with reference to FIGS. 2C to 2E, detailed descriptions thereof will be omitted.

In the present embodiment, since the auxiliary insulating layer 26 is positioned below the crystallization catalyst particles 22 as shown in FIG. 3B, in operation ST5 of performing crystallization shown in FIG. 3F, when the crystallization catalyst particles 22 are spread, the auxiliary insulating layer 26 may getter the crystallization catalyst particles 22. Therefore, it is possible to further reduce the amount of residual crystallization catalyst particles 22 in the polysilicon region 20.

Subsequently, with reference to FIG. 3G, operation ST8 to pattern the auxiliary insulating layer 26 in the same pattern as the insulating layer 24a is performed. At this time, the insulating layer 24 is used as a mask to pattern the auxiliary insulating layer 26. In this case, the insulating layer 24 and the auxiliary insulating layer 26 have different etch selection values. However, aspects of the present invention are not limited thereto and the insulating layer 24 and the auxiliary insulating layer 26 may have the same etch selectivity.

The remaining insulating layer 24 and auxiliary insulating layer 26 are used as an etch stopper to form a thin film transistor. A case in which the insulating layer 24 and the auxiliary insulating layer 26 are used as an etch stopper to form the thin film transistor will be described below in more detail with respect to a method of manufacturing a thin film transistor.

FIGS. 4A to 4G are cross-sectional views sequentially illustrating processes of a method of crystallizing an amorphous silicon layer 200 according to another modified embodiment.

In the present embodiment, as shown in FIG. 4A, the buffer layer 12 and the amorphous silicon layer 200 are formed on the substrate 10. Subsequently, as shown in FIG. 4B, the auxiliary insulating layer 26 is formed on the amorphous silicon layer 200. Next, as shown in FIG. 4C, the crystallization catalyst particles 22 are formed on the amorphous silicon layer 200. Subsequently, as shown in FIG. 4D, the insulating layer 24a is formed. Then, as shown in FIG. 4E, the insulating layer 24a and the auxiliary insulating layer 26 are patterned to selectively remove the crystallization catalyst particles 22. Next, as shown in FIG. 4F, a portion of the amorphous silicon layer 200 is crystallized to form the polysilicon region 20 having a first region 20a and second regions 20b, and an uncrystallized region 200′ remains at sides of the polysilicon region 20. Then, as shown in FIG. 4G, the uncrystallized region 200′ is removed.

That is, in the present embodiment, in the operation ST4 to selectively remove the insulating layer, the auxiliary insulating layer 26 is patterned together with an in the same pattern as the insulating layer 24a. Therefore, the present embodiment is similar to the embodiment of FIGS. 3A to 3H, except that the operation ST8 to separately pattern the auxiliary insulating layer 26 is omitted. Since the auxiliary insulating layer 26 is removed together with the insulating layer 24a, it is possible to reduce a number of processes as compared to the embodiment of FIGS. 3A to 3H. Therefore, it is possible to simplify processes and to reduce a manufacturing cost.

Hereinafter, a method of manufacturing a thin film transistor using the method of crystallizing an amorphous silicon layer 200 described above and a thin film transistor manufactured thereby will be described below in more detail.

The method of manufacturing the thin film transistor includes forming a semiconductor layer by applying the method of crystallizing the amorphous silicon layer 200 as described above. Furthermore, the method includes forming a gate electrode, a source electrode, and a drain electrode together with the semiconductor layer. However, a description of a portion of the method, such as the crystallizing an amorphous silicon layer is omitted and operations corresponding to the method of crystallizing an amorphous silicon layer will be described with reference to the preceding drawings. In the related figures, a same or similar elements are denoted by the same reference numerals used in previously discussed embodiments.

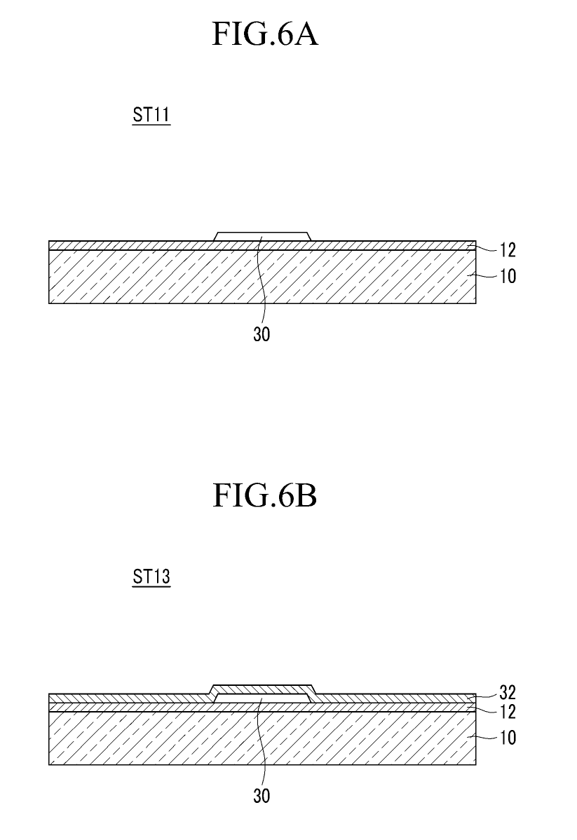

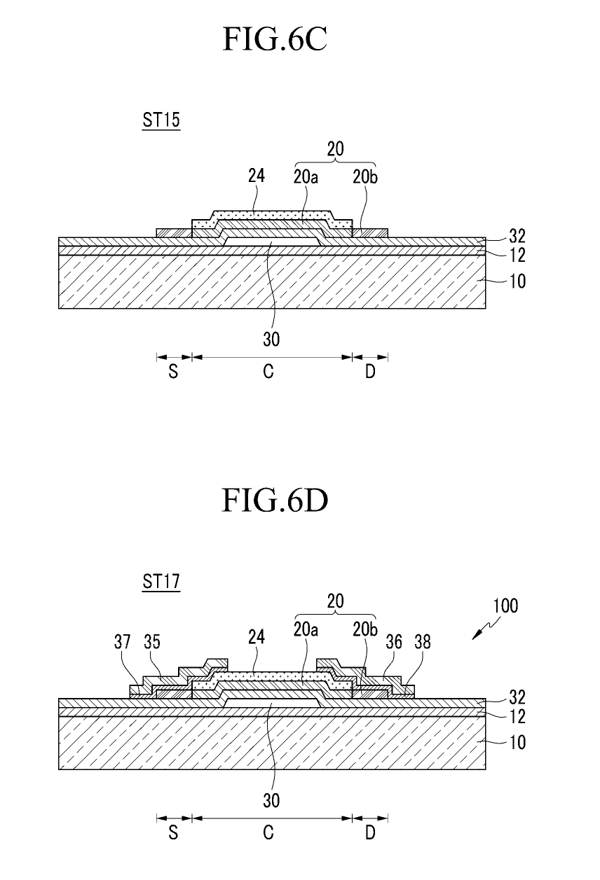

FIG. 5 is a flowchart illustrating a method of manufacturing a thin film transistor according to another embodiment, and FIGS. 6A to 6D are cross-sectional views sequentially illustrating processes of the method of manufacturing a thin film transistor according to the present embodiment. As shown in FIG. 5, the method of manufacturing a thin film transistor includes operation to form a gate electrode ST11, form a gate insulating layer ST13, form a semiconductor layer ST15, and form a source electrode and a drain electrode ST17. The method of manufacturing will be described in more detail with reference to FIGS. 6A to 6D.

First, as shown in FIG. 6A, in operation S11 to form a gate electrode, a gate electrode 30 is formed on the buffer layer 12 of the substrate 10. However, aspects of the present invention are not limited thereto, and the buffer layer 12 is not necessarily needed and may not be formed considering the kind of the substrate 10, process conditions, and other conditions. The gate electrode 30 is formed of a metal having excellent conductivity and is formed of molybdenum tungsten (MoW), aluminum (Al), or an alloy of them. The gate electrode 30 is formed by forming a metal layer and patterning the metal layer. However aspects of the present invention are not limited thereto and the gate electrode 30 can be formed by various known methods.

Subsequently, as shown in FIG. 6B, in operation S13 of forming a gate insulating layer, a gate insulating layer 32 is formed to cover the gate electrode 30. The gate insulating layer 32 is formed of silicon oxide or silicon nitride by vapor deposition. Next, as shown in FIG. 6C, in operation ST15 to form a semiconductor layer, a semiconductor layer 20, containing polysilicon, and an insulating layer 24 are formed. The semiconductor layer 20 and the insulating layer 24 are formed by a method similar to that as shown in FIGS. 2A to 2F. Therefore, the semiconductor layer 20 includes a first region 20a crystallized by SGS or metal induced crystallization, and second regions 20b crystallized by metal induced lateral crystallization.

Referring to FIG. 2B, since the crystallization catalyst particles 22 are positioned between the semiconductor layer 20 and the insulating layer 24, in a thin film transistor 100 (see FIG. 6D) having been subject to crystallizing operation ST5 of shown in FIG. 2E, an amount of crystallization catalyst particles 22 contained between the semiconductor layer 20 and the insulating layer 24 is larger than an amount of crystallization catalyst particles 22 contained in the semiconductor layer 20 or the insulating layer 24.

Subsequently, as shown in FIG. 6D, in operation S17 to form a source electrode and a drain electrode, a source electrode 35 and a drain electrode 36 are formed to be electrically connected to a source region S and a drain region D of the semiconductor layer 20, respectively. In the present embodiment, the source region S and the drain region D are formed by separately forming amorphous silicon layers 37 and 38, which are doped at a high concentration. Alternatively, the source region S and the drain region D may be formed by doping two portions of the semiconductor layer 20 by an ion doping method at a high concentration, without forming the separate amorphous silicon layers 37 and 38 at the high concentration. However, aspects of the present invention are not limited thereto, and the source region S and the drain region D may be formed by other suitable methods.

The amorphous silicon layers 37 and 38, the source electrode 35 and the drain electrode 36 are formed by depositing a component material and patterning the component material. However, aspects of the present invention are not limited thereto and the amorphous silicon layers 37 and 38, the source electrode 35 and the drain electrode 36 can be formed by various methods using various materials.

In the present embodiment, in a process of patterning the amorphous silicon layers 37 and 38 and the source and drain electrodes 35 and 36, the insulating layer 24 is used as an etch stopper. That is, since the insulating layer 24 formed in operation S13 to form the semiconductor layer is used as an etch stopper, a separate process is not added. Therefore, it is possible to simplify processes and to reduce the manufacturing cost. However, aspects of the present invention are not limited thereto and it is possible to remove the insulating layer 24 and form a separate etch stopper in operation ST13 to form a semiconductor layer.

In the present embodiment, crystallization is performed in a state in which crystallization catalyst particles 22 (see FIG. 2D) and the insulating layer 24 are positioned corresponding to a channel region C. Therefore, in the semiconductor layer 20, a region corresponding to the channel region C is crystallized by SGS or metal induced crystallization to form the first region 20a. Also, regions corresponding to the source and drain regions S and D are crystallized by metal induced lateral crystallization to form the second regions 20b.

In the present embodiment, since the crystallizing operation ST5 is performed in a state in which the crystallization catalyst particles 22 are positioned corresponding to only the channel region C, a region of the amorphous silicon layer 200 (see FIG. 2D), on which there are no crystallization catalyst particles 22 thereon, is used as a region to getter the crystallization catalyst particles 22. Therefore, it is possible to reduce the concentration of residual crystallization catalyst particles 22 in the formed semiconductor layer 20 and to minimize leakage current.

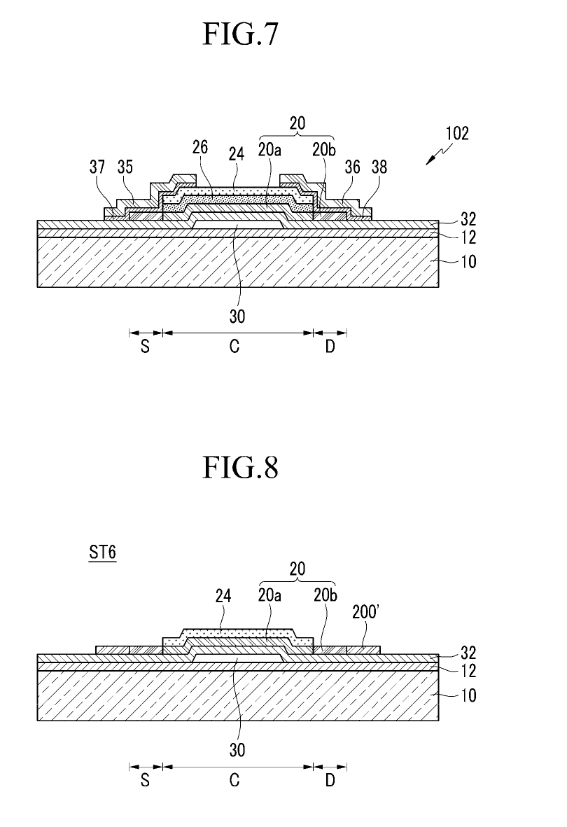

FIG. 7 is a cross-sectional view illustrating a thin film transistor 102 manufactured by a method of manufacturing the thin film transistor 102 according to another embodiment. In the present embodiment, operation ST11 to form a gate electrode (see FIG. 5 and FIG. 6A), operation ST13 to form a gate insulating layer (see FIG. 5 and FIG. 6B), and operation ST15 to form source and drain electrodes (see FIG. 5 and FIG. 6D) are similar operations to those in the embodiment of FIG. 5, and an operation ST17 to form a semiconductor layer (see FIG. 5) is different from that of the embodiment of FIG. 5, and thus will be mainly described.

Referring to FIG. 7, the thin film transistor 102 according to the present embodiment further includes an auxiliary insulating layer 26 between the insulating layer 24 and the semiconductor layer 20. The auxiliary insulating layer 26 is formed in operation ST7 to form the auxiliary insulating layer 26, and is performed between operation ST1 to form an amorphous silicon layer 200 and operation ST2 to position crystallization catalyst particles 22, as shown in FIG. 3B or FIG. 4B.

Then, the auxiliary insulating layer 26, which is formed on an entire surface of the amorphous silicon layer 200 (see FIG. 3B or FIG. 4B) is patterned to corresponding to the insulating layer 24 after operation ST5 to crystallize an amorphous silicon layer and/or operation ST6 to remove an uncrystallized region, as shown in FIG. 3G. Alternatively, as shown in FIG. 4D, the insulating layer 24 and the auxiliary insulating layer 26 may be patterned together in operation ST4 to selectively remove the crystallization catalyst particles 22.

Referring to FIG. 3B or FIG. 4B, since the crystallization catalyst particles 22 are positioned between the insulating layer 24 and the auxiliary insulating layer 26, even after crystallizing operation ST5, shown FIG. 3F or FIG. 4F, an amount of crystallization catalyst particles 22 contained between the auxiliary insulating layer 26 and the insulating layer 24 is larger than an amount of crystallization catalyst particles contained in the auxiliary insulating layer 26 or the insulating layer 24.

In the present embodiment, there is shown a case in which the insulating layer 24 is used as an etch stopper. However, aspects of the present invention are not limited thereto and the insulating layer 24 may be removed. In such a case, only the auxiliary insulating layer 26 may be used as an etch stopper, or both of the insulating layer 24 and the auxiliary insulating layer 26 may be removed and a separate etch stopper may be formed.

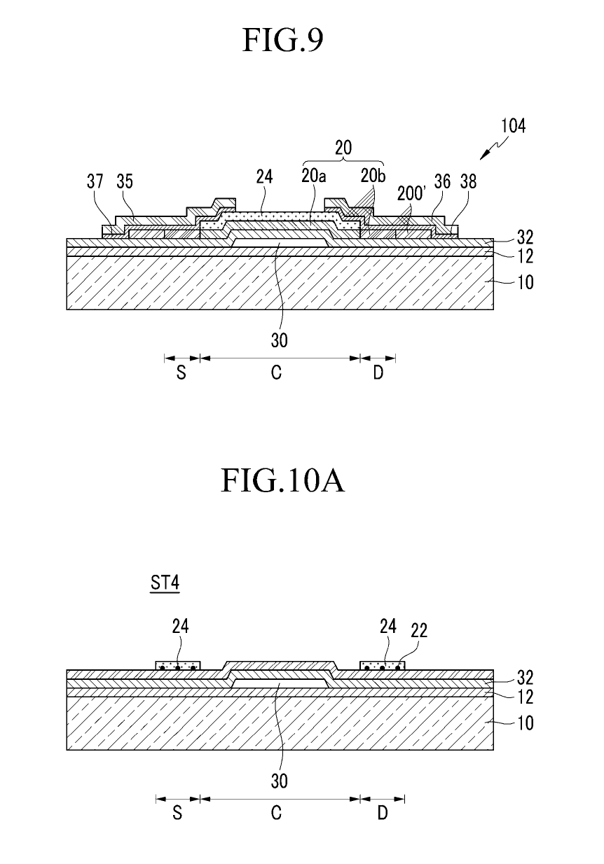

FIG. 8 is a cross-sectional view illustrating operation ST6 to remove an uncrystallized region in a method of manufacturing a thin film transistor according to another embodiment. FIG. 9 is a cross-sectional view illustrating a thin film transistor 104 manufactured by the method of manufacturing the thin film transistor according to the present embodiment.

In the present embodiment, operation ST11 to form a gate electrode (see FIG. 5 and FIG. 6A), operation ST13 to form a gate insulating layer (see FIG. 5 and FIG. 6B), and operation ST15 to form source and drain electrodes (see FIG. 5 and FIG. 6D) are similar operations as those in the embodiment of FIG. 5, and operation ST17 to form a semiconductor layer (see FIG. 5) is different from the embodiment of FIG. 5 and thus will be mainly described.

The present embodiment is similar to the embodiment of FIG. 5, except that a whole uncrystallized region 200′ is not removed, but rather a portion of the uncrystallized region 200′ remains in operation ST6 to remove an uncrystallized region remaining after operation ST17. According to the present embodiment, as shown in FIG. 9, a source region S and a drain region D of a thin film transistor 104 include the uncrystallized region 200′ together with the second regions 20b. The second regions 20b are regions crystallized by metal induced lateral crystallization. Therefore, the thin film transistor 104 is capable of reducing current flowing in an OFF state during operations of the thing film transistor 104, thereby improving properties in the OFF state. The channel region C is composed of a region crystallized by metal induced crystallization, as in the embodiment of FIG. 5.

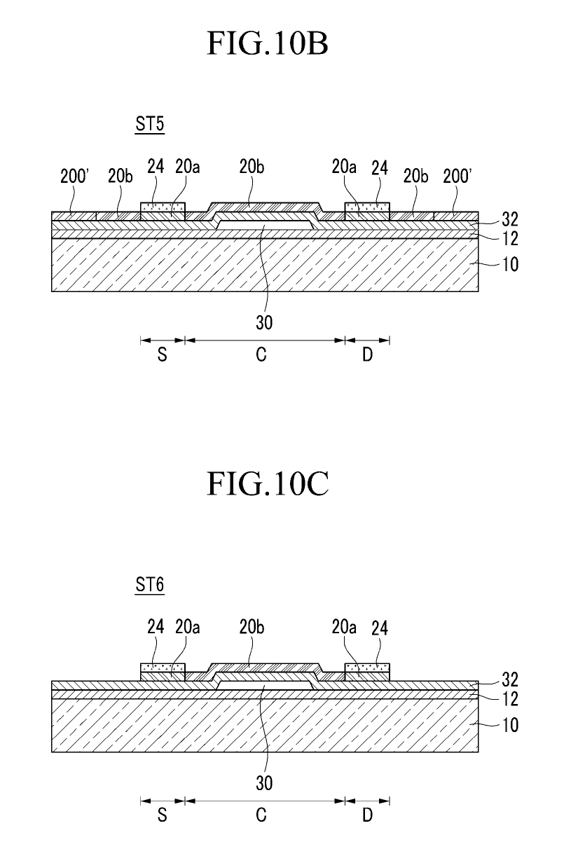

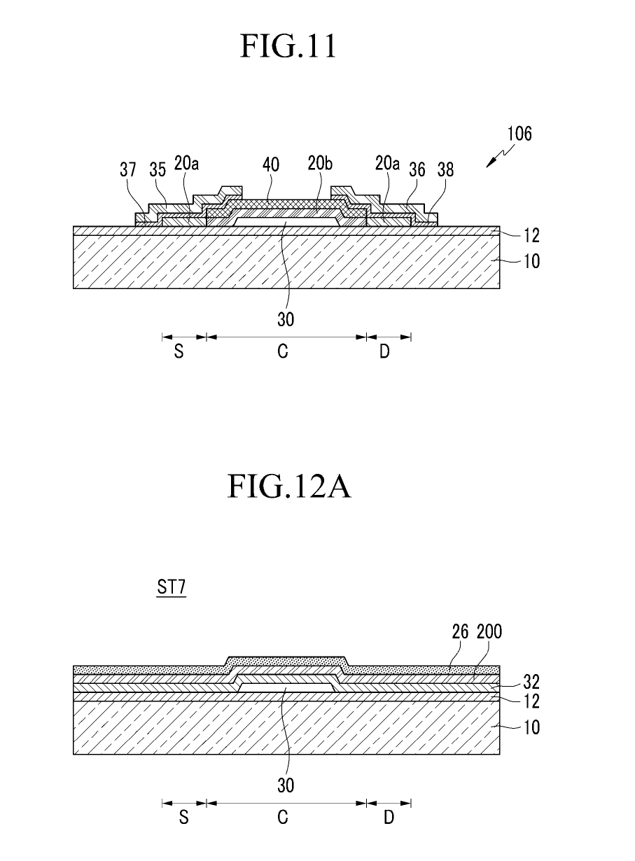

FIGS. 10A to 10C are cross-sectional views illustrating some of processes of a method of manufacturing a thin film transistor according to another embodiment. FIG. 11 is a cross-sectional view illustrating the thin film transistor manufactured by the method of manufacturing the thin film transistor according the present embodiment. The present embodiment is different from the embodiment of FIG. 5 in only operation ST17 to form a semiconductor layer (see FIG. 5) and thus this operation ST17 will be mainly described. In particular, the present embodiment is different from the embodiment of FIG. 5 with respect to positions where the insulating layer 24 and the crystallization catalyst particles 22 are selectively formed in operation ST17. Thus, only operation ST17 will be described in detail and descriptions of other elements and operations will be omitted.

In the present embodiment, operation ST1 to form an amorphous silicon layer, operation ST2 to position crystallization catalyst particles, and operation ST3 to form an insulating layer are sequentially performed. Since the operations ST1, ST2 and ST3 have been described with reference to FIG. 1, FIGS. 2A to 2C, FIGS. 3A to 3C, and FIGS. 4A to 4C, detailed descriptions of them are omitted. Subsequently, as shown in FIG. 10A, in operation ST4 to selectively remove crystallization catalyst particles 22, the insulating layer 24 and the crystallization catalyst particles 22 are removed except for portions defined as a source region S and a drain regions D.

Next, as shown in FIG. 10B, if a heat treatment is performed in operation ST5 to crystallize an amorphous silicon layer, the source and drain regions S and D have the insulating layer 24 and the crystallization catalyst particles 22 disposed thereon. The source and drain regions S and D are crystallized by SGS or metal induced crystallization to form the first regions 20a. Also, both sides of each the first regions 20a is crystallized by metal induced lateral crystallization to form the second regions 20b, and an other potion of the amorphous silicon layer remains as the uncrystallized region 200′. Subsequently, as shown in FIG. 10C, in operation ST6 to remove an uncrystallized region, the uncrystallized region 200′ and the second regions 20b formed on the outer side of the source and drain regions S and D are removed.

In the present embodiment, since the insulating layer 24 is formed corresponding to the source and drain regions S and D, it is difficult for the insulating layer 24 to function as an etch stopper. Accordingly, before or after operation ST6 of removing an uncrystallized region, it is possible to remove the insulating layer 24 and to then form a separate etch stopper 40 (see FIG. 11).

In a thin film transistor 106 manufactured according to the present embodiment, as shown in FIG. 11, a channel region C is crystallized by metal induced lateral crystallization to form a second region 20b. Also, regions corresponding to source and drain regions S and D are crystallized by SGS or metal induced crystallization to form first regions 20a. Therefore, it is possible to reduce an amount of crystallization catalyst particles 22 in the channel region C, thereby improving the properties of the thin film transistor 106.

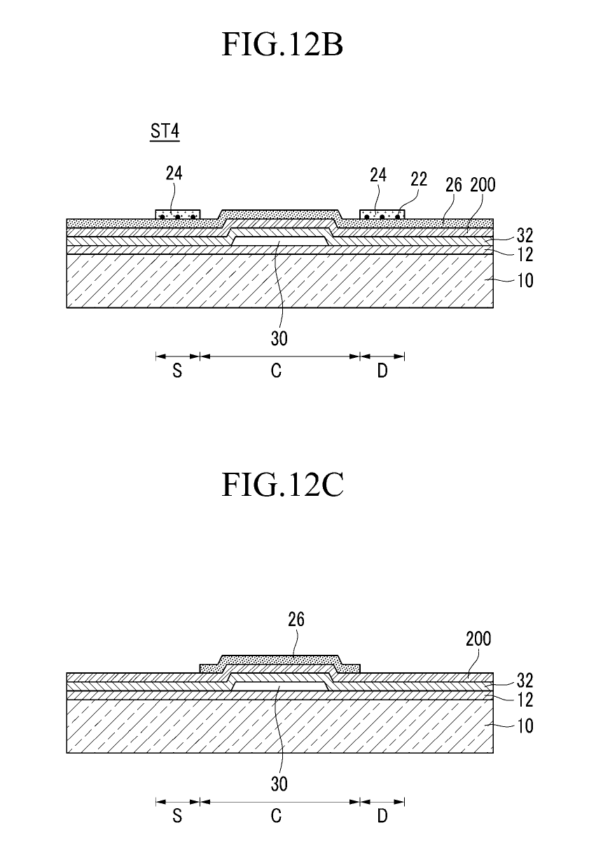

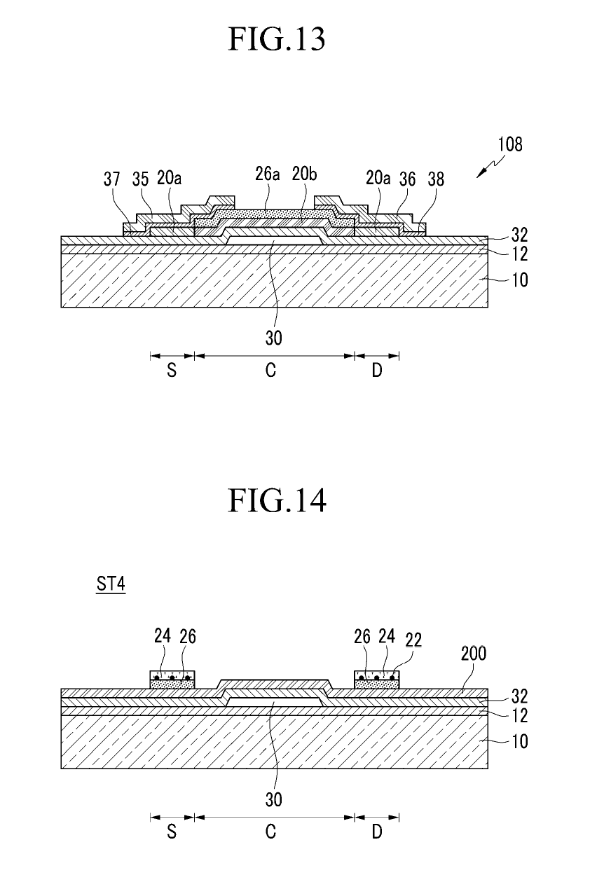

FIGS. 12A to 12C are cross-sectional views illustrating some processes in operation ST17 to form a semiconductor layer according to another embodiment. FIG. 13 is a cross-sectional view illustrating a thin film transistor 108 manufactured by a method of manufacturing a thin film transistor according to the present embodiment.

The present embodiment is different from the embodiment of FIGS. 10A to 10C in operation ST17 to form a semiconductor layer (see FIG. 5), which will be mainly described. In the present embodiment, an auxiliary insulating layer 26 is formed between an insulating layer 24 and a semiconductor layer 20. After operation ST1 to form an amorphous silicon layer, as shown in FIG. 12A, operation ST7 to form an auxiliary insulating layer is performed to form an auxiliary insulating layer 26 on an amorphous silicon layer 200. This auxiliary insulating layer 26 is capable of gettering crystallization catalyst particles 22.

Subsequently, operation ST2 to position crystallization catalyst particles and operation ST3 to form an insulating layer are sequentially performed. Next, as shown in FIG. 12D, in operation ST4 to selectively remove crystallization catalyst particles, a region of the insulating layer 24, except for source and drain regions S and D, is removed. Subsequently, a heat treatment is performed in operation ST5 to crystallize an amorphous silicon layer and then the remaining insulating layer 24 is removed as shown in FIG. 12C.

Then, an auxiliary insulating layer 26 is patterned to correspond to a channel region C. This auxiliary insulating layer 26 is capable of functioning as an etch stopper of a source electrode 35 and a drain electrode 36 (see FIG. 13). In the present embodiment, since the auxiliary insulating layer 26 having a gettering function can be used as an etch stopper, it is unnecessary to form a separate etch stopper. Therefore, it is possible to improve process efficiency. Next, operation ST6 to remove an uncrystallized region is performed and then amorphous silicon layers 37 and 38, which are doped at a high concentration, and a source electrode 35 and a drain electrode 36 are formed. As a result, a thin film transistor 108 as shown in FIG. 13 is formed.

In the present embodiment, a potion of the auxiliary insulating layer 26 is removed between operation ST5 to form an amorphous silicon layer and operation ST6 to remove an uncrystallized region. However, aspects of the present invention are not limited thereto. Therefore, after operation ST6 to remove an uncrystallized region, a portion of the auxiliary insulating layer 26 may also be removed.

FIG. 14 is a cross-sectional view illustrating operation ST4 to selectively remove crystallization catalyst particles of a semiconductor layer in a method of manufacturing a thin film transistor according to another embodiment. The present embodiment is the same as the manufacturing method according to the embodiment of FIGS. 12A to 12C, except that in a region except for source and drain regions S and D, an auxiliary insulating layer 26 is removed together with an insulating layer 24 in operation ST4.

In the present embodiment, since an insulating layer 24 and an auxiliary insulating layer 26 are formed corresponding to source and drain regions S and D, it is difficult for the insulating layer 24 and the auxiliary insulating layer 26 to be used as an etch stopper. For this reason, after operation ST5 to crystallize an amorphous silicon layer, it is possible to remove the insulating layer 24 and the auxiliary insulating layer 26 and to form a separate etch stopper.

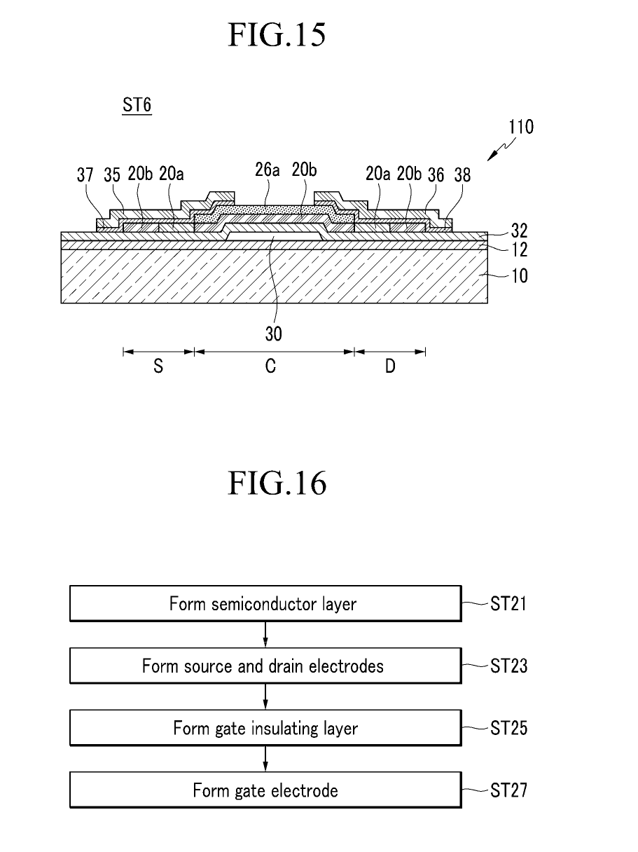

FIG. 15 is a cross-sectional view illustrating a thin film transistor 110 manufactured by a method of manufacturing a thin film transistor according to another embodiment. The present embodiment is the same as the embodiment of FIGS. 10A to 10C, except that, in operation ST6 to remove an uncrystallized region, source and drain regions S and D include second regions 20b crystallized by SGS or metal induced crystallization as well as first regions 20a crystallized by metal induced lateral crystallization. Although not shown in the drawing, aspects of the present invention allow for the source and drain regions S and D to include a portion of an uncrystallized region 200′.

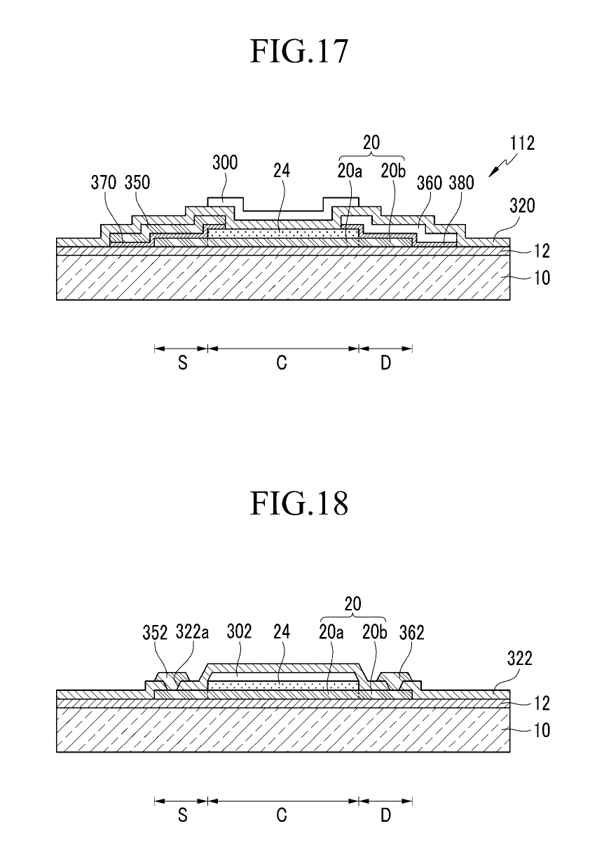

FIG. 16 is a flowchart illustrating a method of manufacturing a thin film transistor according to another embodiment. FIG. 17 is a cross-sectional view illustrating a thin film transistor 112 manufactured according to the present embodiment. The manufacturing method according to the present embodiment includes operation ST21 to form a semiconductor layer, operation ST23 to form source and drain electrodes, operation ST25 to form a gate insulating layer on the semiconductor layer and the source and drain electrodes, and operation S27 to form a gate electrode, as shown in FIG. 16. That is, the present embodiment has a top gate structure in which a gate electrode 300 is positioned on a semiconductor layer 20.

Operation ST21 to form a semiconductor layer, operation ST23 to form source and drain electrodes, operation ST25 to form a gate insulating layer on the semiconductor layer and the source and drain electrodes, and operation S27 to form a gate electrode, all correspond to operation ST15 to form a semiconductor layer, operation ST17 to form source and drain electrodes, operation ST13 to form an insulating layer, and operation ST11 to form a gate electrode in the above-mentioned embodiments, respectively. Therefore, detailed descriptions thereof are omitted.

Referring to FIG. 17, the thin film transistor 112 includes a semiconductor layer 20 having first regions 20a and second regions 20b formed on a buffer layer 12, which is formed on a substrate 10. Also, an insulating layer 24 (an etch stopper) is formed on the semiconductor layer 20. Amorphous layers 370 and 380, which are doped at a high concentration. A source electrode 350 and a drain electrode 360 are sequentially formed on the insulating layer 24 to respectively correspond to a source region S and a drain region D of the semiconductor layer 20. A gate insulating layer 320 is formed to cover the source and drain electrodes 350 and 360 and a gate electrode 300 is formed on the gate insulating layer 320 to correspond to a channel region C.

In FIG. 17, there is shown a case in which the channel region C is composed of a first region 20a and the source and drain regions S and D are composed of second regions 20b. However, aspects of the present invention are not limited thereto and the methods of manufacturing a thin film transistor having a bottom gate structure and the thin film transistors manufactured by the manufacturing methods corresponding the previously discussed embodiments may be used.

FIG. 18 is a cross-sectional view illustrating a thin film transistor according to another embodiment. The present embodiment is another example of the top gate structure and uses an insulating layer 24 as a gate insulating layer. That is, the insulating layer 24, formed corresponding to the channel region C, is used as a gate insulating layer, and a gate electrode 302 having a width the same as or smaller than the insulating layer 24 is formed on the insulating layer 24. Also, an interlayer insulating layer 322 is formed to cover the semiconductor layer 20 and the insulating layer 24. A contact hole 322a is formed in the interlayer insulating layer 322. A source electrode 352 and a drain electrode 362 are formed on the interlayer insulating layer 322 to be respectively electrically connected to a source region S and a drain region D via the contact hole 322a.

In FIG. 18, there is shown a case in which a channel region C is composed of a first region 20a and the source and drain regions S and D are composed of second regions 20b. However, aspects of the present invention are not limited thereto. That is, methods of manufacturing a thin film transistor having a bottom gate structure and the thin film transistors manufactured by the manufacturing methods corresponding the previously discussed embodiments may be used. The thin film transistor manufactured according to the present embodiment described above can be applied to a display such as an active-matrix-type liquid crystal display, an organic light emitting diode display. However, the present invention is not limited thereto. It is apparent that the present invention can be applied to various electronic devices.

Hereinafter, the embodiments will be described in more detail in reference to an experimental example and a comparative example of the present invention.

### Experimental Example

An amorphous silicon layer was formed on a buffer layer formed on a substrate by vapor deposition. Nickel particles were positioned as crystallization catalyst particles on the entire surface of the amorphous silicon layer. An insulating layer was formed to cover the nickel particles. Next, the insulating layer, except for a portion, was removed to selectively position the nickel particles. A heat treatment was performed to crystallize the amorphous silicon layer, thereby forming a semiconductor layer according to aspects of the present invention.

### Comparative Example

An amorphous silicon layer was crystallized by processes which are the same as the experimental example, except that the process of removing the insulating layer except for a partial region is not performed. Thus, the comparative example has a semiconductor layer not formed according to aspects of the present invention.

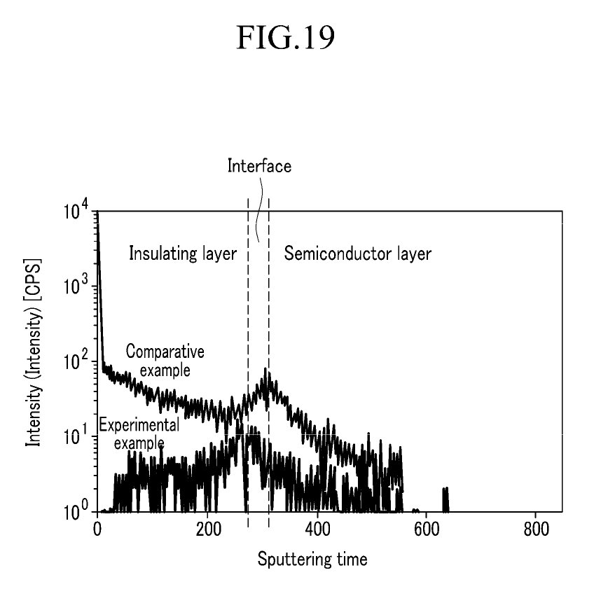

FIG. 19 shows profiles of SIMS (secondary ion mass spectrometry) indicating nickel particle distributions in the semiconductor layers and the insulating layers in the experimental example and the comparative example. Referring to intensity which is a y axis in FIG. 19, it can be seen that concentrations of nickel particles in the insulating layer and the semiconductor layer of the experimental example are remarkably lower than concentrations of nickel particles in the insulating layer and the semiconductor layer of the comparative example. This is because, in the experimental example, a portion of the amorphous silicon layer, on which there are no nickel particles, functioned as a gettering site.

Although a few embodiments of the present invention have been shown and described, it would be appreciated by those skilled in the art that changes may be made in this embodiment without departing from the principles and spirit of the invention, the scope of which is defined in the claims and their equivalents.

1. A crystallizing method comprising:
forming an amorphous silicon layer;
positioning crystallization catalyst particles on the amorphous silicon layer to be separated from each other;
selectively removing the crystallization catalyst particles from a portion of the amorphous silicon layer; and
crystallizing the amorphous silicon layer by a heat treatment.

2. The crystallizing method of claim 1, wherein a crystallization region crystallized in the crystallizing of the amorphous silicon layer comprises:
a first region positioned below the crystallization catalyst particles and crystallized by super grain silicon (SGS) or metal induced crystallization (MIC); and
second regions positioned on both sides of the first region and crystallized by metal induced lateral crystallization (MILC).

3. The crystallizing method of claim 1, further comprising removing an uncrystallized region after the crystallizing of the amorphous silicon layer.

4. The crystallizing method of claim 1, wherein the selectively removing of the crystallization catalyst particles comprises:
forming an insulating layer to cover the crystallization catalyst particles; and
patterning the insulating layer.

5. The crystallizing method of claim 4, further comprising forming an auxiliary insulating layer on the amorphous silicon layer between the forming of the amorphous silicon layer and the positioning of the crystallization catalyst particles.

6. The crystallizing method of claim 5, wherein in the patterning of the insulating layer, the auxiliary insulating layer is patterned together with the insulating layer in a same pattern as the insulating layer.

7. The crystallizing method of claim 5, further comprising patterning the auxiliary insulating layer in the same pattern as the insulating layer after the crystallizing of the amorphous silicon layer.

8. The crystallizing method of claim 1, wherein the crystallization catalyst particles include nickel (Ni), and
wherein the crystallization catalyst particles are deposited at a density of 10¹¹ to 10¹⁵ particles/cm² in the positioning of the crystallization catalyst particles.

9. The crystallizing method of claim 1, wherein the heat treatment of the crystallizing of the amorphous silicon layer is performed at a temperature 200° C. to 900° C.

10. A method of manufacturing a thin film transistor including a semiconductor layer having a channel region, a source region and a drain region defined, a gate electrode formed corresponding to the channel region with a gate insulating layer interposed therebetween, and a source electrode and a drain electrode respectively electrically connected to the source region and the drain region, wherein forming the semiconductor layer comprises:
forming an amorphous silicon layer;
positioning crystallization catalyst particles to be separated from each other;
selectively removing the crystallization catalyst particles from a portion of the amorphous silicon layer; and
crystallizing the amorphous silicon layer by a heat treatment.

11. The method of manufacturing a thin film transistor of claim 10, wherein a crystallization region crystallized in the crystallizing comprises:
a first region positioned below the crystallization catalyst particles and crystallized by super grain silicon (SGS) or metal induced crystallization (MIC); and
second regions positioned on both sides of the first region and crystallized by metal induced lateral crystallization (MILC).

12. The method of manufacturing of claim 10, further comprising removing an uncrystallized region after the crystallizing of the amorphous silicon layer.

13. The method of manufacturing of claim 10, wherein the selectively removing of the crystallization catalyst particles comprises:
forming an insulating layer to cover the crystallization catalyst particles; and
patterning the insulating layer.

14. The method of manufacturing of claim 13, further comprising forming an auxiliary insulating layer on the amorphous silicon layer between the forming of the amorphous silicon layer and the positioning of the crystallization catalyst particles.

15. The method of manufacturing of claim 14, wherein in the patterning of the insulating layer, the auxiliary insulating layer is patterned together with the insulating layer in a same pattern as the insulating layer.

16. The method of manufacturing of claim 14, further comprising patterning the auxiliary insulating layer in the same pattern as the insulating layer after the crystallizing of the amorphous silicon layer.

17. The method of manufacturing of claim 16, wherein the insulating layer and the auxiliary insulating layer have different etch selection values.

18. The method of manufacturing of claim 14, wherein either the insulating layer, or the insulating layer and the auxiliary insulating layer are removed after the crystallizing of the amorphous silicon layer.

19. The method of manufacturing of claim 11, wherein in the selectively positioning of the crystallization catalyst particles, the crystallization catalyst particles are positioned corresponding to the channel region, and
wherein the channel region includes the first region and both the source region and the drain region include the second regions.

20. The method of manufacturing of claim 19, further comprising removing an uncrystallized region after the crystallizing of the amorphous silicon layer,
wherein, in the removing of the uncrystallized region, the whole uncrystallized region is removed such that both the source region and the drain region include only the second regions.

21. The method of manufacturing of claim 19, further comprising removing an uncrystallized region after the crystallizing of the amorphous silicon layer,
wherein, in the removing of the uncrystallized region, only a portion of the uncrystallized region is removed such that both the source region and the drain region include portions of the uncrystallized region together with the second regions.

22. The method of manufacturing of claim 11, wherein in the selectively positioning of the crystallization catalyst particles, the crystallization catalyst particles are positioned corresponding to a portion of, or the whole, of the source region and the drain region, and
wherein the channel region includes the second regions and both the source region and the drain region include the first region.

23. The method of manufacturing of claim 22, further comprising removing an uncrystallized region after the crystallizing of the amorphous silicon layer,
wherein, in the removing of the uncrystallized region, the second regions on the outer side of the first region are removed together with the uncrystallized region such that both the source region and the drain region include only the first region.

24. The method of manufacturing of claim 22, further comprising removing an uncrystallized region after the crystallizing of the amorphous silicon layer,
wherein, in the removing of the uncrystallized region, the uncrystallized region is removed such that both the source region and the drain region include the second regions together with the first region.

25. The method of manufacturing of claim 10, further comprising forming the gate electrode and forming the gate insulating layer on the gate electrode before the forming of the semiconductor layer; and
forming the source and drain electrodes after the forming of the semiconductor layer.

26. The method of manufacturing of claim 10, after the forming of the semiconductor layer, further comprising:
forming the source electrode and the drain electrode;
forming the gate insulating layer on the insulating layer, the source electrode and the drain electrode; and
forming the gate electrode on the gate insulating layer.

27. The method of manufacturing of claim 10, wherein the insulating layer functions as an etch stopper of the source electrode and the drain electrode.

28. The method of manufacturing of claim 10, wherein the crystallization catalyst particles include nickel (Ni), and
wherein the crystallization catalyst particles are deposited at a density of 10¹¹ to 10¹⁵ particles/cm² in the positioning of the crystallization catalyst particles.

29. The method of manufacturing of claim 10, wherein the heat treatment of the crystallizing of the amorphous silicon layer is performed at a temperature 200° C. to 900° C.

30. A thin film transistor comprising:
a semiconductor layer having a channel region, a source region and a drain regions defined;
a gate electrode formed corresponding to the channel region with a gate insulating layer interposed therebetween;
a source electrode electrically connected to the source region; and
a drain electrode electrically connected to the drain region,
wherein the channel region includes a first region crystallized by super grain silicon (SGS) or metal induced crystallization (MIC), and
wherein both the source region and the drain region include second regions crystallized by metal induced lateral crystallization (MILC).

31. The thin film transistor of claim 30, wherein both the source region and the drain region include only the second regions.

32. The thin film transistor of claim 30, wherein both the source region and the drain region include an uncrystallized region formed of amorphous silicon together with the second regions.

33. The thin film transistor of claim 30, further comprising an insulating layer formed corresponding to the channel region.

34. The thin film transistor of claim 33, further comprising an auxiliary insulating layer disposed between the insulating layer and the semiconductor layer.

35. The thin film transistor of claim 33, wherein the gate insulating layer is positioned on the gate electrode,
wherein the semiconductor layer is positioned on the gate insulating layer,
wherein the insulating layer is positioned on the semiconductor layer, and
wherein the source electrode and the drain electrode are positioned on the semiconductor layer.

36. The thin film transistor of claim 33, wherein the insulating layer is positioned on the semiconductor layer,
wherein the source electrode and the drain electrode are positioned on the semiconductor layer,
wherein the gate insulating layer is positioned on the source electrode and the drain electrode, and
wherein the gate electrode is positioned on the gate insulating layer.

37. The thin film transistor of claim 33, wherein the insulating layer functions as an etch stopper of the source electrode and the drain electrode.

38. The thin film transistor of claim 33, wherein an amount of crystallization catalyst particles contained in an interface between the insulating layer and the semiconductor layer is larger than an amount of crystallization catalyst particles in the insulating layer or the semiconductor layer.

39. The thin film transistor of claim 34, wherein an amount of crystallization catalyst particles contained in an interface between the insulating layer and the auxiliary insulating layer is larger than an amount of crystallization catalyst particles in the insulating layer or the auxiliary insulating layer.

40. The method of manufacturing a thin film transistor of claim 25, wherein the insulating layer functions as an etch stopper of the source electrode and the drain electrode.

41. The method of manufacturing a thin film transistor of claims 26, wherein the insulating layer functions as an etch stopper of the source electrode and the drain electrode.

42. The thin film transistor of claim 34, wherein the insulating layer functions as an etch stopper of the source electrode and the drain electrode.

43. The thin film transistor of claim 35, wherein the insulating layer functions as an etch stopper of the source electrode and the drain electrode.

44. The thin film transistor of claim 36, wherein the insulating layer functions as an etch stopper of the source electrode and the drain electrode.
